(19) United States
(12) Patent Application Publication
(10) Pub. No.: US 2026/0301804 A1
(43) Pub. Date: Oct. 1, 2026

(54) QUICK-SET COMPONENT FOR STATIC RANDOM ACCESS MEMORY

(71) Applicant: International Business Machines Corporation, Armonk, NY (US)

(72) Inventors: Derek LEU, Stormville, NY (US); Bishan HE, Poughkeepsie, NY (US); Dongho LEE, Poughkeepsie, NY (US)

(21) Appl. No.: 19/093,238

(22) Filed: Mar. 27, 2025

(51) Int. Cl. G11C 11/412

(52) U.S. Cl. CPC G11C 11/4125

(57) ABSTRACT

A voltage potential is equalized between rows or columns of a static random access memory (SRAM) array using an equalize component of a quick-set component. A plurality of the memory cells in the SRAM array are simultaneously set or reset using the quick-set component. The equalize component may be configured to mitigate cell biasing during a normal operation.

### BACKGROUND

The present invention relates to static random access memory (SRAM), and for example, relates to a quick-set component for SRAM.

### SUMMARY

In one embodiment, a static random access memory (SRAM) device is provided. In this embodiment, the SRAM device includes an SRAM array having memory cells arranged in rows and columns, and a quick-set component coupled to the SRAM array. The quick-set component includes an equalize component and is configured to simultaneously set or reset a plurality of the memory cells in the SRAM array. The equalize component is configured to mitigate cell biasing during a normal operation.

In another embodiment, a computing system is provided. In this embodiment, the computing system includes an attack detection component configured to detect a side channel attack, and a static random access memory (SRAM) device. The SRAM device comprises an SRAM array having memory cells arranged in rows and columns, and a quick-set component coupled to the SRAM array. The quick-set component is configured to, based on an indication of a detection of the side channel attack, simultaneously set or reset a plurality of the memory cells in the SRAM array.

In yet another embodiment, a computer-implemented method is provided. In this embodiment, the method includes equalizing, using an equalize component of a quick-set component, a voltage potential between rows or columns of a static random access memory (SRAM) array, and simultaneously setting or resetting a plurality of memory cells in the SRAM array using the quick-set component.

### BRIEF DESCRIPTION OF THE DRAWINGS

FIG. 1 is a block diagram of an example computing system described herein.

FIGS. 2A and 2B are schematic diagrams showing examples of static random access memory devices having quick-set components.

FIGS. 2C and 2D are conceptual diagrams showing examples of quick-set patterns.

FIG. 3 is a diagram of an example computing environment in which systems and/or methods described herein may be implemented.

FIG. 4 is a diagram of example components of one or more devices of FIG. 1.

FIG. 5 is a flowchart of an example process associated with control of static random access memory described herein.

### DETAILED DESCRIPTION

The following detailed description of example implementations refers to the accompanying drawings. The same reference numbers in different drawings may identify the same or similar elements.

Static random access memory (SRAM) has become an integral component in modern computing systems, providing high-speed data storage and retrieval capabilities for various applications. As the demand for faster and more efficient computing continues to grow, SRAM technology faces challenges in maintaining data integrity and security. One of the technical hurdles in SRAM design is the need to quickly and efficiently set or reset large numbers of memory cells simultaneously, particularly in scenarios where rapid data purging is required to mitigate security threats. As used herein, “simultaneously” means “at the same time,” “during a same time period,” “in a single time slot,” or “in a single clock cycle.” For example, “simultaneously” may refer to “at the same time” or “at approximately the same time,” where “approximately” refers to a time difference between a first event and a second event within a range that is selected such that the first event and the second event occur within a temporal window configured to allow for a corresponding functionality.

Current SRAM architectures often rely on sequential access methods to modify the contents of memory cells, which can be time-consuming and inefficient when dealing with large arrays. This limitation becomes problematic in situations where immediate data clearing is necessary, such as in response to detected security breaches or side-channel attacks. The inability to rapidly reset or set multiple memory cells simultaneously can leave sensitive data vulnerable to exploitation, potentially compromising the integrity of the computing system.

Furthermore, existing SRAM designs frequently struggle with cell biasing issues during normal operation, which can lead to data instability and increased power consumption. This technical challenge arises from voltage fluctuations and leakage currents within the memory array, potentially causing unintended state changes in memory cells. The lack of effective mechanisms to mitigate these biasing effects can result in reduced reliability and performance degradation of SRAM devices, particularly in high-density memory configurations.

Another technical obstacle in current SRAM technology is the difficulty in implementing flexible and efficient memory initialization patterns across rows or columns of the array. This limitation hampers the ability to quickly establish known states within the memory, which is useful for testing, diagnostics, and certain computational algorithms. The absence of hardware-level support for diverse initialization patterns restricts the versatility of SRAM devices and can lead to increased complexity in software-level memory management, ultimately impacting overall system performance and functionality.

Implementations of this disclosure address problems such as these by providing a quick-set component for SRAM that enables simultaneous setting or resetting of multiple memory cells within an SRAM array. The quick-set component may include an equalize component configured to mitigate cell biasing during normal operation, thereby improving stability and reliability of the SRAM device. In some implementations, the quick-set component may be coupled to rows or columns of the SRAM array, allowing for flexible and efficient memory initialization patterns.

The quick-set component may include a first inverter associated with a first logical state (sometimes referred to as a “true” logical state) and a second inverter associated with a second logical state (sometimes referred to as a “complement” logical state) complement to the first logical state (sometimes referred to as a “false” logical state). Each inverter may include a P-channel field effect transistor (PFET) and an N-channel field effect transistor (NFET) controlled by a single gate control. This configuration simplifies the circuit design and reduces the number of control signals required, potentially lowering overall circuit complexity. The term “inverter” as used herein refers to a logic gate that implements logical negation. For example, an inverter may convert a logical ‘1’ input to a logical ‘0’ output, and vice versa. In some implementations, different types of transistors or logic gates may be included to achieve the inverting function.

The equalize component may be implemented as a field effect transistor (FET) disposed between the first and second inverters. During normal operation, the equalize component may provide a stable ground voltage to the SRAM array, effectively mitigating biasing issues that can arise from voltage fluctuations and leakage currents. The term “equalize component” in this context refers to a circuit element that balances voltage levels between different parts of the SRAM array. For instance, it may ensure that the virtual ground levels for true and complement sides of the memory cells remain equal. In some implementations, the equalize component may be implemented using other circuit configurations, such as a transmission gate or a resistive element.

The quick-set component may be configured to implement various quick-set patterns on the rows or columns of the SRAM array. These patterns may include, but are not limited to, blanket ‘1’ patterns, blanket ‘0’ patterns, even striping patterns, odd striping patterns, or block patterns. The term “quick-set pattern” refers to a predefined configuration of logical states applied simultaneously to multiple memory cells. For example, a blanket ‘1’ pattern sets all selected cells to a logical ‘1’ state. A blanket ‘0’ pattern sets all selected cells to a logical ‘0’ state. An even striping pattern sets even-numbered rows or columns to logical ‘1’ or ‘0’ states. An odd striping pattern sets odd-numbered rows or columns to logical ‘1’ or ‘0’ states. A block pattern sets a block of adjacent rows or columns to logical ‘1’ or ‘0’ states. Some implementations may include more complex patterns or allow for user-defined custom patterns.

In some implementations, the quick-set component may be activated during the functional mode of the SRAM device to mitigate cache-targeted exploits. This capability allows for rapid purging of sensitive data in response to detected security threats, such as side-channel attacks. The term “side-channel attack” refers to a type of security exploit that attempts to gain unauthorized access to information through the analysis of the physical implementation of a computer system, rather than weaknesses in the implemented algorithm itself. For instance, a side-channel attack might analyze power consumption patterns or electromagnetic emissions to infer sensitive data. Some implementations may include additional security features, such as randomized quick-set patterns or time-delayed purging to further obfuscate data from potential attackers.

The disclosed quick-set component improves upon traditional SRAM designs by reducing the time required to initialize or clear large portions of memory. This technical advancement enables more efficient memory management and enhances system responsiveness in scenarios requiring rapid data purging or initialization. In some implementations, the quick-set component may be hardware-configurable to operate on either row or column directions of the SRAM array, providing flexibility in memory manipulation that can be tailored to specific application requirements or hardware constraints.

By integrating the quick-set component with an attack detection system, the disclosure provides a proactive approach to memory security. Upon detection of a potential security threat, the system can trigger the quick-set component to perform simultaneous setting or resetting of multiple memory cells, effectively purging sensitive data before it can be exploited. This technical solution represents an improvement over existing computer-implemented security measures by combining rapid response capabilities with efficient memory manipulation at the hardware level.

In some implementations, the quick-set component includes a first inverter associated with a first logical state and a second inverter associated with a second logical state complement to the first logical state, each controlled by a single gate control. Accordingly, an advantage of the single gate control for each inverter is simplified circuit design, reducing the number of control signals required. Additionally, an advantage of the single gate control configuration is improved switching speed by ensuring that the PFET and NFET transition states simultaneously. Furthermore, an advantage of this inverter configuration is reduced circuit complexity, which can lead to easier implementation in dense memory arrays.

In some implementations, the quick-set component includes an equalize component configured as a FET disposed between the first and second inverters. Accordingly, an advantage of the equalize component is its ability to mitigate cell biasing during normal operation by providing a stable ground voltage to the SRAM array. Additionally, an advantage of the equalize component is improved stability and reliability of the SRAM device by reducing voltage fluctuations and leakage currents. Furthermore, an advantage of the equalize component is its contribution to maintaining predictable and consistent switching behavior in the SRAM cells, which is particularly beneficial in low-power and high-speed applications.

In some situations, a first processor and a second processor may be included in a system. While each processor may have a dedicated level 1 cache (data cache and instruction cache), the processors may share a level 2 cache. In some situations, the second processor may request access to the level 2 cache but the first processor may not authorize the second processor to read what the first processor has written to the level 2 cache. In this regard, the first processor may use the quick-set patterns to clear what the first processor has written to the level 2 cache to prevent the second processor from reading what the first processor has written to the level 2 cache. Conversely, the second processor may use the quick-set patterns to clear what the second processor has written to the level 2 cache to prevent the first processor from reading what the second processor has written to the level 2 cache.

In some implementations, the quick-set component is configured to implement various quick-set patterns on the rows or columns of the SRAM array, including blanket ‘1’ patterns, blanket ‘0’ patterns, even striping patterns, odd striping patterns, or block patterns. Accordingly, an advantage of the configurable quick-set patterns is increased flexibility in memory initialization and data manipulation. Additionally, an advantage of the quick-set patterns is improved efficiency in memory management tasks, such as rapid data clearing or setting specific data configurations. Furthermore, an advantage of the quick-set pattern capability is enhanced system responsiveness in scenarios requiring immediate data purging, such as in response to detected security threats.

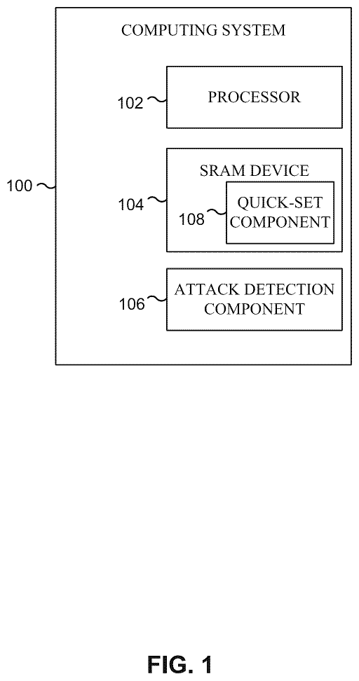

FIG. 1 is a block diagram of an example of a computing system. As shown, the computing system 100 includes a processor 102, an SRAM device 104, and an attack detection component 106, which are configured to interact with each other to provide efficient memory management and enhanced security features. As shown, the SRAM device 104 includes a quick-set component 108.

The processor 102 is configured to execute instructions and process data within the computing system 100. In some implementations, processor 102 may include multiple processing cores, cache memory, and specialized circuitry for handling various computational tasks. The processor 102 interfaces with other components of the system, including the SRAM device 104 and the attack detection component 106, to coordinate operations and manage data flow.

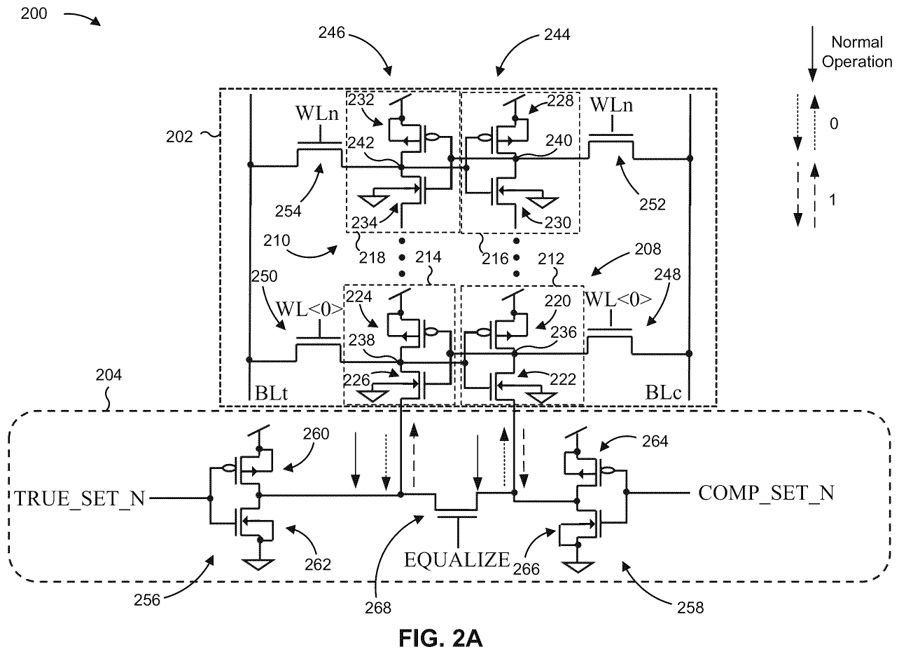

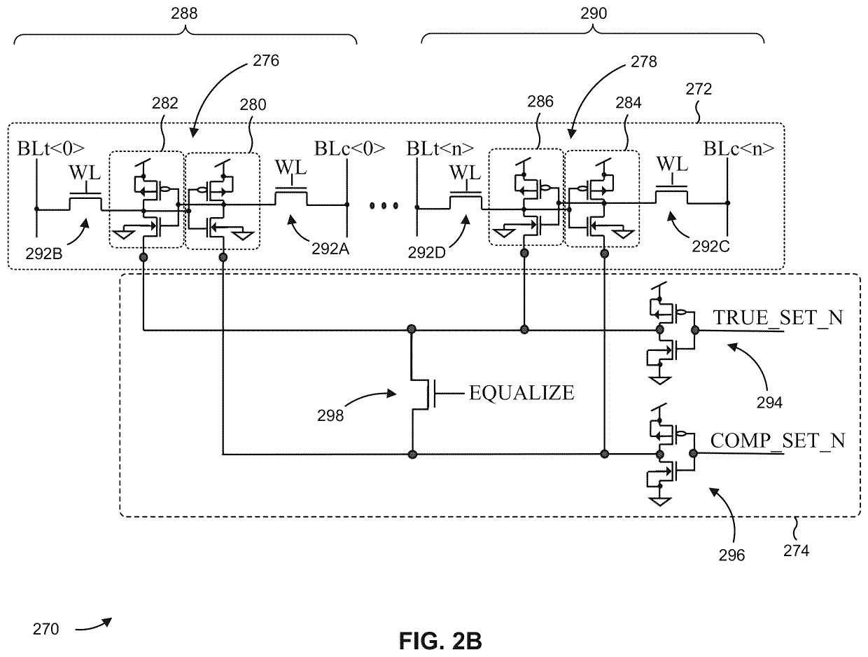

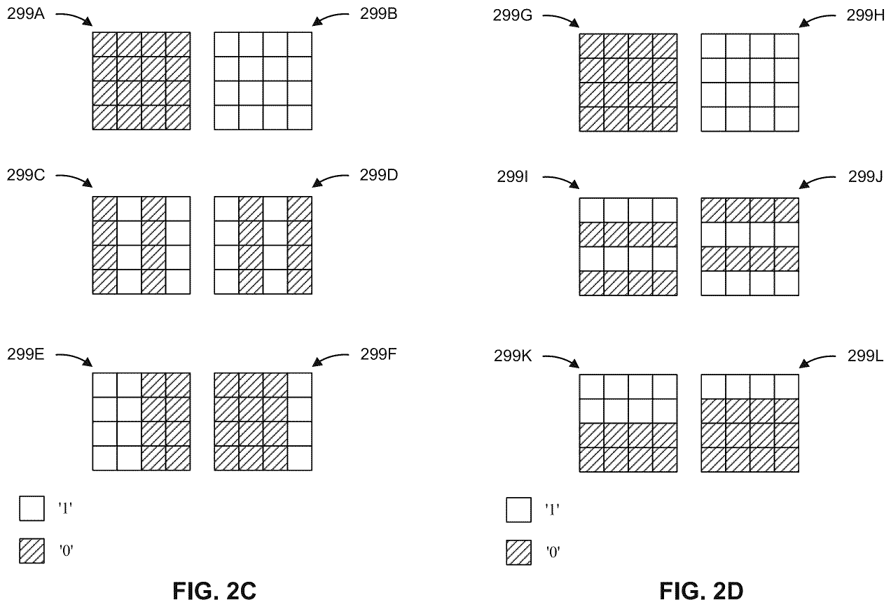

SRAM is a type of volatile memory that provides high-speed data storage and retrieval capabilities. In some implementations, the SRAM device 104 may be organized into multiple banks or arrays of memory cells arranged in rows and columns. The SRAM device 104 may be directly connected to the processor 102, allowing for rapid access to stored data and instructions. In some implementations, quick-set component 108 enables simultaneous setting or resetting of multiple memory cells, as described in further detail below in connection with FIG. 2.

The attack detection component 106 is designed to monitor system operations and identify potential security threats, such as side-channel attacks. In some implementations, attack detection component 106 may employ various algorithms and heuristics to analyze system behavior, memory access patterns, and other relevant parameters. The attack detection component 106 is in communication with both the processor 102 and the SRAM device 104, allowing it to trigger protective measures when a threat is detected.

In operation, the processor 102 may issue read and write commands to the SRAM device 104 during normal system operation. These commands are typically transmitted over a high-speed bus or interconnect, with the SRAM device 104 responding by either storing or retrieving data as requested. The attack detection component 106 may continually monitor these operations, analyzing patterns and characteristics that may indicate a potential security threat.

When the attack detection component 106 identifies a possible side-channel attack or other security risk, the attack detection component 106 may signal the quick-set component 108 to initiate protective measures. In some implementations, initiating protective measures may include activating the quick-set functionality within the SRAM device 104 to rapidly clear or reset large portions of memory, effectively purging potentially compromised data. The processor 102 may issue specific commands to activate the quick-set component 108, either in response to signals from the attack detection component 106 or as part of routine memory management operations.

In some implementations, the computing system 100 may also include additional components not explicitly shown in FIG. 1. For example, the system may incorporate a memory controller that mediates communications between the processor 102 and the SRAM device 104, managing memory access requests and coordinating quick-set operations. Additionally, the system may include various input/output interfaces, network connections, and other peripheral devices that enhance its functionality and versatility.

The attack detection component 106 may employ various techniques to identify potential security threats. In some implementations, it may monitor power consumption patterns, electromagnetic emissions, or timing characteristics of memory access operations. By analyzing these parameters, the attack detection component 106 can detect anomalies that may indicate an ongoing side-channel attack or other security breach.

The processor 102, the SRAM device 104, and the attack detection component 106 may communicate using standardized protocols and interfaces. In some implementations, this may include high-speed serial interfaces, parallel buses, or specialized memory access protocols designed for low-latency communication. The specific communication methods used may be optimized for the particular requirements of the system, balancing factors such as speed, power consumption, and security.

In some implementations, the computing system 100 may be configured to operate in different modes, each with specific security and performance characteristics. For example, a high-security mode may activate additional monitoring features within the attack detection component 106 and enable more frequent use of the quick-set functionality in the SRAM device 104. Conversely, a high-performance mode may prioritize processing speed and memory access efficiency, potentially with reduced security monitoring.

In some implementations, the quick-set component 108 may be utilized to facilitate lower power modes and/or to increase memory availability. By rapidly setting or resetting large portions of memory, the quick-set component 108 may enable efficient power management strategies. For instance, when entering a low-power state, the quick-set component 108 may quickly clear unused memory regions, allowing those sections to be powered down or placed in a reduced power state. This approach may result in decreased overall power consumption of the SRAM device 104. Additionally, the quick-set component 108 may be employed to rapidly initialize memory blocks, potentially reducing the time required to bring memory online when transitioning from a low-power state to an active state. In terms of memory availability, the quick-set component 108 may be used to quickly deallocate and reset memory regions that are no longer in use, making them immediately available for new allocations. This capability may enhance memory utilization efficiency, potentially reducing the need for additional physical memory in some systems. The quick-set component's ability to operate on entire rows or columns simultaneously may also enable more granular control over memory power states and availability, allowing for fine-tuned optimization of system resources based on current workload demands.

FIG. 2A illustrates a schematic diagram of an SRAM device 200 according to some implementations of the present disclosure. In some implementations, the SRAM device 200 may be, be similar to, include, or be included in the SRAM device 104 shown in FIG. 1. The SRAM device 200 includes an SRAM array 202 and a quick-set component 204. The SRAM array 202 includes a plurality of memory cells arranged in rows and columns, with two exemplary SRAM cells 208 and 210 shown in detail. The quick-set component 204 is coupled to the SRAM array 202 and is configured to simultaneously set or reset multiple memory cells within the array.

In some implementations, each SRAM cell within the SRAM array 202 includes two cross-coupled inverters. For example, the SRAM cell 208 includes inverters 212 and 214, while the SRAM cell 210 includes inverters 216 and 218. These inverters are fundamental to the bistable operation of the SRAM cells, allowing them to maintain their state without the need for constant refreshing. The inverter 212 of the SRAM cell 208 includes a P-channel field effect transistor (PFET) 220 and an N-channel field effect transistor (NFET) 222. Similarly, the inverter 214 includes a PFET 224 and an NFET 226. In the SRAM cell 210, the inverter 216 is composed of a PFET 228 and an NFET 230, while the inverter 218 includes a PFET 232 and an NFET 234. This configuration of complementary transistors allows for low static power consumption and high noise immunity during normal operation of the SRAM device 200.

The cross-coupling of the inverters in each SRAM cell creates two stable states, represented by complement (CMP) nodes 236 and 240, and true (TRU) nodes 238 and 242. In some implementations, these nodes store the logical state of the memory cell, with one node at a high voltage level and the other at a low voltage level, depending on the stored bit value. The SRAM cells 208 and 210 are arranged along columns 244 and 246, respectively. This columnar organization facilitates efficient addressing and access to the memory cells within the SRAM array 202. In some implementations, multiple columns may be grouped together to form memory banks, allowing for parallel access and improved performance.

Access to the SRAM cells is provided through NFETs 248, 250, 252, and 254. These transistors act as pass gates, controlling the connection between the internal nodes of the SRAM cells and the bitlines used for reading and writing data. The gates of these NFETs may be connected to wordlines, which are activated during read and write operations to select specific rows of memory cells. The quick-set component 204 includes inverters 256 and 258, which are used for the rapid setting or resetting of memory cells within the SRAM array 202. The inverter 256 includes a PFET 260 and an NFET 262, while the inverter 258 is composed of a PFET 264 and an NFET 266. These inverters are designed to drive the virtual ground lines connected to the SRAM cells, enabling simultaneous modification of multiple cell states.

An equalize component 268 is disposed between the inverters 256 and 258 within the quick-set component 204. In some implementations, the equalize component 268 may be implemented as a FET. The function of the equalize component 268 is to mitigate cell biasing during normal operation of the SRAM device 200, ensuring stable and reliable performance. During normal operation, the equalize component 268 may provide a stable ground voltage to the SRAM array 202. This helps to prevent voltage fluctuations and leakage currents that could potentially disturb the stored data in the memory cells. By maintaining a consistent ground reference, the equalize component 268 contributes to the overall stability and reliability of the SRAM device 200.

In some implementations, the quick-set component 204 may be coupled to either the rows or columns of the SRAM array 202. In some implementations, coupling the quick-set component 204 to the columns of the SRAM array 202 may offer advantages in terms of vertical data manipulation and efficient column-wise operations. This configuration may allow for rapid setting or resetting of entire columns simultaneously, which may be beneficial for applications that frequently access or modify data in a columnar fashion. On the other hand, coupling a quick-set component to the rows of a SRAM array, as described below in connection with FIG. 2B, may provide advantages for horizontal data manipulation and row-wise operations. This arrangement may enable quick initialization or clearing of entire rows at once, which may be particularly useful for applications that process data in a row-oriented manner or require frequent row-based memory management. The choice between column and row coupling may depend on the specific requirements of the system, such as data access patterns, memory organization, and the nature of the operations most commonly performed on the SRAM array 202.

The operation of the SRAM device 200 involves interactions between its components. During a read operation, for example, the wordline connected to a specific row of memory cells may be activated, turning on the access transistors (e.g., NFETs 248, 250, 252, and 254) for that row. This allows the stored data to be sensed on the bitlines connected to the selected memory cells. For write operations, the quick-set component 204 may be utilized. By manipulating the virtual ground lines connected to multiple memory cells simultaneously, the quick-set component 204 can rapidly set or reset the states of these cells. This capability is useful for initializing large portions of the memory array or for quickly clearing sensitive data in response to security threats.

In some implementations, the quick-set component 204 may be configured to implement various quick-set patterns on the rows or columns of the SRAM array 202. These patterns may include blanket ‘1’ or ‘0’ settings, where all selected cells are set to the same state, or more complex patterns such as striping, where alternating columns are set to different states. This flexibility allows for efficient memory initialization and management in various applications.

The SRAM device 200 may also incorporate additional circuitry not explicitly shown in FIG. 2A, such as sense amplifiers for reading data, write drivers for modifying cell states, and control logic for managing the overall operation of the memory array. These components work in concert with the illustrated elements to provide fast and reliable memory access while supporting the advanced features enabled by the quick-set component 204.

The quick-set component 204 may enhance the security of the SRAM device 200, particularly in mitigating various types of side-channel attacks and cache-targeted exploits. By enabling rapid and simultaneous setting or resetting of multiple memory cells, the quick-set component 204 provides a mechanism for protecting sensitive data stored in the SRAM array 202. This capability may be useful in scenarios where immediate data purging is necessary to prevent unauthorized access or data leakage.

In the context of side-channel attacks, such as those exploiting power consumption patterns or electromagnetic emissions, the quick-set component 204 may offer a countermeasure. When a potential security threat is detected, possibly by an external attack detection component, the quick-set component 204 may be activated to rapidly clear or randomize the contents of specific memory regions or even the entire SRAM array 202. This action may disrupt the attacker's ability to gather meaningful information through side-channel analysis, as the data being targeted may be quickly altered or removed before it can be fully exploited.

The quick-set component 204 may also help mitigate cache-targeted exploits, including those related to speculative execution vulnerabilities like Spectre. In these types of attacks, malicious programs may attempt to access sensitive data stored in cache memory by exploiting the processor's speculative execution mechanisms. By enabling fast and efficient clearing of cache lines implemented in SRAM, the quick-set component 204 may reduce the window of opportunity for such attacks. For instance, upon detecting suspicious cache access patterns, the system may utilize the quick-set component 204 to rapidly reset or randomize the contents of vulnerable cache regions, thereby limiting the amount of sensitive data that could potentially be exposed through speculative execution side channels.

The quick-set component 204 may provide additional security features to mitigate risks associated with branch prediction unit vulnerabilities. A branch prediction unit is a component within a processor that attempts to predict the outcome of conditional branch instructions. Branch instructions are used to control the flow of execution in a program, and their outcome may depend on various factors, such as the values of data in memory. The branch prediction unit uses various techniques to guess which way a branch will go, such as keeping track of the history of previous branch outcomes. If the prediction is correct, the processor can continue executing instructions without having to wait for the actual outcome of the branch. This can improve performance, but it also introduces a potential security vulnerability. Data leakage onto the branch prediction unit occurs when the outcome of a branch instruction depends on sensitive information, such as the value of a secret key. An attacker could potentially exploit this by crafting a malicious program that causes the processor to speculatively execute instructions based on the secret information. Even if the speculative execution is later discarded, the branch prediction unit may still have learned something about the secret information. This information could then be used to infer the secret value. Malicious programs could exploit side channel attacks to piece together sensitive information that has leaked out onto the branch prediction unit. The disclosed invention aims to mitigate this risk by providing a way to quickly reset or set the contents of SRAM, which can help to reduce the amount of data leakage that can occur during speculative execution.

In some implementations, the quick-set component 204 may be configured to rapidly clear or randomize the contents of SRAM regions that interact with the branch prediction unit. This capability may help reduce the potential for data leakage onto the branch prediction unit during speculative execution. By quickly modifying the state of memory cells associated with branch instructions, the quick-set component 204 may disrupt attempts by malicious programs to exploit branch prediction patterns for inferring sensitive information. In some implementations, the quick-set component 204 may be utilized to implement dynamic memory obfuscation techniques, periodically altering the memory layout to make it more challenging for attackers to predict and exploit branch outcomes. This approach may enhance the overall resilience of the system against side channel attacks by reducing the consistency and predictability of branch-related data in the SRAM array 202.

FIG. 2B illustrates a schematic diagram of another example of an SRAM device 270 according to some implementations of the present disclosure. In some implementations, the SRAM device 270 may be similar to, include, or be included in the SRAM device 104 shown in FIG. 1. The SRAM device 270 includes an SRAM array 272 and a quick-set component 274. The SRAM array 272 includes a plurality of memory cells arranged in rows and columns, with two exemplary SRAM cells 276 and 278 shown in detail. The quick-set component 274 is coupled to the SRAM array 272 and is configured to simultaneously set or reset multiple memory cells within the array.

In some implementations, each SRAM cell within the SRAM array 272 includes two cross-coupled inverters. For example, the SRAM cell 276 includes inverters 280 and 282, while the SRAM cell 278 includes inverters 284 and 286. These inverters are fundamental to the bistable operation of the SRAM cells, allowing them to maintain their state without the need for constant refreshing. The structure and operation of these inverters may be similar to those described in connection with FIG. 2A, including the use of complementary PFETs and NFETs to form each inverter.

The SRAM cells 276 and 278 are arranged along rows 288 and 290, respectively. This row-based organization facilitates efficient addressing and access to the memory cells within the SRAM array 272. In some implementations, multiple rows may be grouped together to form memory banks, allowing for parallel access and improved performance.

Access to the SRAM cells is provided through NFETs 292A, 292B, 292C, and 292D. These transistors act as pass gates, controlling the connection between the internal nodes of the SRAM cells and the bitlines (BLs) used for reading and writing data. In this row-based configuration, the gates of these NFETs may be connected to wordlines (WLs), which are activated during read and write operations to select specific rows of memory cells. The NFETs 292A and 292B are associated with SRAM cell 276, while NFETs 292C and 292D are associated with SRAM cell 278.

The quick-set component 274 includes inverters 294 and 296, which are used for the rapid setting or resetting of memory cells within the SRAM array 272. These inverters may be similar in structure to the inverters 256 and 258 described in connection with FIG. 2A, including PFETs and NFETs arranged to drive the virtual ground lines connected to the SRAM cells. However, in this row-based configuration, the inverters 294 and 296 are designed to enable simultaneous modification of multiple cell states along entire rows of the SRAM array 272.

An equalize component 298 is disposed between the inverters 294 and 296 within the quick-set component 274. In some implementations, the equalize component 298 may be implemented as a FET. The function of the equalize component 298 is to mitigate cell biasing during normal operation of the SRAM device 270, ensuring stable and reliable performance. During normal operation, the equalize component 298 may provide a stable ground voltage to the SRAM array 272. This helps to prevent voltage fluctuations and leakage currents that could potentially disturb the stored data in the memory cells. By maintaining a consistent ground reference, the equalize component 298 contributes to the overall stability and reliability of the SRAM device 270.

In the row-based configuration of FIG. 2B, the quick-set component 274 is coupled to the rows of the SRAM array 272. This arrangement allows for efficient horizontal data manipulation and row-wise operations. The quick-set component 274 may enable rapid initialization or clearing of entire rows simultaneously, which can be particularly useful for applications that process data in a row-oriented manner or require frequent row-based memory management. This configuration may offer advantages in terms of horizontal data manipulation and efficient row-wise operations, complementing the column-wise capabilities described in connection with FIG. 2A.

The operation of the SRAM device 270 involves interactions between its components. During a read operation, for example, the wordline connected to a specific row of memory cells may be activated, turning on the access transistors (e.g., NFETs 292A, 292B, 292C, and 292D) for that row. This allows the stored data to be sensed on the bitlines connected to the selected memory cells. For write operations, the quick-set component 274 may be utilized. By manipulating the virtual ground lines connected to multiple memory cells simultaneously along a row, the quick-set component 274 can rapidly set or reset the states of these cells. This capability is useful for initializing large portions of the memory array or for quickly clearing sensitive data in response to security threats.

In some implementations, the quick-set component 274 may be configured to implement various quick-set patterns on the rows of the SRAM array 272. These patterns may include blanket ‘1’ or ‘0’ settings, where all selected cells in a row are set to the same state, or more complex patterns such as striping, where alternating cells within a row are set to different states. This flexibility allows for efficient memory initialization and management in various applications, particularly those that benefit from row-wise data manipulation.

The SRAM device 270 may also incorporate additional circuitry not explicitly shown in FIG. 2B, such as sense amplifiers for reading data, write drivers for modifying cell states, and control logic for managing the overall operation of the memory array. These components work in concert with the illustrated elements to provide fast and reliable memory access while supporting the advanced features enabled by the quick-set component 274. The row-based configuration may require specific adaptations in the peripheral circuitry to optimize performance and functionality compared to the column-based arrangement shown in FIG. 2A.

In this configuration, the SRAM device 270 efficiently orchestrates rapid row-wise memory operations, ensuring enhanced performance in applications that benefit from horizontal data access patterns. The integration of the quick-set component 274 with the row-based SRAM array 272 allows for seamless and simultaneous manipulation of entire rows of memory cells, thereby enhancing operational efficiency and providing flexibility in memory management tasks. This row-oriented architecture complements the column-based approach described in FIG. 2A, offering system designers a choice of memory configurations to best suit their specific application requirements.

FIGS. 2C and 2D show conceptual examples of quick-set patterns, as described herein. FIG. 2C shows examples of column-based quick-set patterns and FIG. 2D shows examples of row-based quick-set patterns. The quick-set component 204 shown in FIG. 2A or the quick-set component 274 shown in FIG. 2B may be configured to implement various quick-set patterns on the columns or rows, respectively, of the SRAM array. The column-based patterns may include, but are not limited to, a column-based blanket ‘0’ pattern 299A, a column-based blanket ‘1’ pattern 299B, a column-based even striping pattern 299C, a column-based odd striping pattern 299D, a column-based block pattern 299E, or a column-based block pattern 299F, among other examples. The row-based patterns may include, but are not limited to, a row-based blanket ‘0’ pattern 299G, a row-based blanket ‘1’ pattern 299H, a row-based even striping pattern 299I, a row-based odd striping pattern 299J, a row-based block pattern 299K, or a row-based block pattern 299L, among other examples.

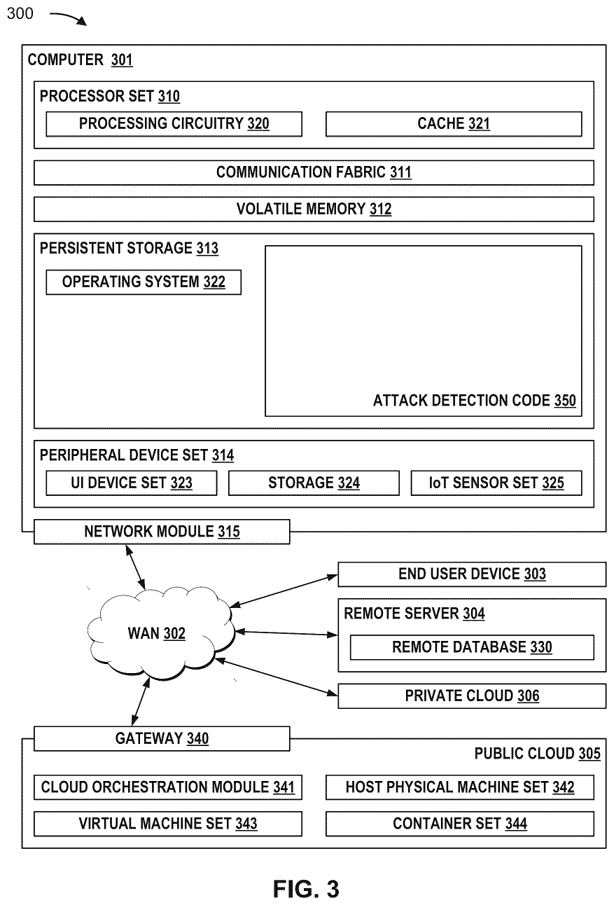

FIG. 3 is a diagram of an example computing environment 300 in which systems and/or methods described herein may be implemented. Various aspects of the present disclosure are described by narrative text, flowcharts, block diagrams of computer systems and/or block diagrams of the machine logic included in computer program product embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment is a term used in the present disclosure to describe any set of one, or more, storage media (also called “mediums”) collectively included in a set of one, or more, storage devices that collectively include machine readable code corresponding to instructions and/or data for performing computer operations specified in a given claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 300 contains an example of an environment for the execution of at least some of the computer code involved in performing the inventive methods, such as attack detection code, shown in block 350. In addition to block 350, computing environment 300 includes, for example, computer 301, wide area network (WAN) 302, end user device (EUD) 303, remote server 304, public cloud 305, and private cloud 306. In this embodiment, computer 301 includes processor set 310 (including processing circuitry 320 and cache 321), communication fabric 311, volatile memory 312, persistent storage 313 (including operating system 322 and block 350, as identified above), peripheral device set 314 (including user interface (UI) device set 323, storage 324, and Internet of Things (IoT) sensor set 325), and network module 315. Remote server 304 includes remote database 330. Public cloud 305 includes gateway 340, cloud orchestration module 341, host physical machine set 342, virtual machine set 343, and container set 344.

COMPUTER 301 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 330. As is well understood in the art of computer technology, and depending upon the technology, performance of a computer-implemented method may be distributed among multiple computers and/or between multiple locations. On the other hand, in this presentation of computing environment 300, detailed discussion is focused on a single computer, specifically computer 301, to keep the presentation as simple as possible. Computer 301 may be located in a cloud, even though it is not shown in a cloud in FIG. 3. On the other hand, computer 301 is not required to be in a cloud except to any extent as may be affirmatively indicated.

PROCESSOR SET 310 includes one, or more, computer processors of any type now known or to be developed in the future. Processing circuitry 320 may be distributed over multiple packages, for example, multiple, coordinated integrated circuit chips. Processing circuitry 320 may implement multiple processor threads and/or multiple processor cores. Cache 321 is memory that is located in the processor chip package(s) and is typically used for data or code that should be available for rapid access by the threads or cores running on processor set 310. Cache memories are typically organized into multiple levels depending upon relative proximity to the processing circuitry. Alternatively, some, or all, of the cache for the processor set may be located “off chip.” In some computing environments, processor set 310 may be designed for working with qubits and performing quantum computing.

Computer readable program instructions are typically loaded onto computer 301 to cause a series of operational steps to be performed by processor set 310 of computer 301 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 321 and the other storage media discussed below. The program instructions, and associated data, are accessed by processor set 310 to control and direct performance of the inventive methods. In computing environment 300, at least some of the instructions for performing the inventive methods may be stored in block 350 in persistent storage 313.

COMMUNICATION FABRIC 311 is the signal conduction path that allows the various components of computer 301 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 312 is any type of volatile memory now known or to be developed in the future. Examples include dynamic type random access memory (RAM) or static type RAM. Typically, volatile memory 312 is characterized by random access, but this is not required unless affirmatively indicated. In computer 301, the volatile memory 312 is located in a single package and is internal to computer 301, but, alternatively or additionally, the volatile memory may be distributed over multiple packages and/or located externally with respect to computer 301.

PERSISTENT STORAGE 313 is any form of non-volatile storage for computers that is now known or to be developed in the future. The non-volatility of this storage means that the stored data is maintained regardless of whether power is being supplied to computer 301 and/or directly to persistent storage 313. Persistent storage 313 may be a read only memory (ROM), but typically at least a portion of the persistent storage allows writing of data, deletion of data and re-writing of data. Some familiar forms of persistent storage include magnetic disks and solid state storage devices. Operating system 322 may take several forms, such as various known proprietary operating systems or open source Portable Operating System Interface-type operating systems that employ a kernel. The code included in block 350 typically includes at least some of the computer code involved in performing the inventive methods.

PERIPHERAL DEVICE SET 314 includes the set of peripheral devices of computer 301. Data communication connections between the peripheral devices and the other components of computer 301 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 323 may include components such as a display screen, speaker, microphone, wearable devices (such as goggles and smart watches), keyboard, mouse, printer, touchpad, game controllers, and haptic devices. Storage 324 is external storage, such as an external hard drive, or insertable storage, such as an SD card. Storage 324 may be persistent and/or volatile. In some embodiments, storage 324 may take the form of a quantum computing storage device for storing data in the form of qubits. In embodiments where computer 301 is required to have a large amount of storage (for example, where computer 301 locally stores and manages a large database) then this storage may be provided by peripheral storage devices designed for storing very large amounts of data, such as a storage area network (SAN) that is shared by multiple, geographically distributed computers. IoT sensor set 325 is made up of sensors that can be used in Internet of Things applications. For example, one sensor may be a thermometer and another sensor may be a motion detector.

NETWORK MODULE 315 is the collection of computer software, hardware, and firmware that allows computer 301 to communicate with other computers through WAN 302. Network module 315 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 315 are performed on the same physical hardware device. In other embodiments (for example, embodiments that utilize software-defined networking (SDN)), the control functions and the forwarding functions of network module 315 are performed on physically separate devices, such that the control functions manage several different network hardware devices. Computer readable program instructions for performing the inventive methods can typically be downloaded to computer 301 from an external computer or external storage device through a network adapter card or network interface included in network module 315.

WAN 302 is any wide area network (for example, the internet) capable of communicating computer data over non-local distances by any technology for communicating computer data, now known or to be developed in the future. In some embodiments, the WAN 302 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 303 is any computer system that is used and controlled by an end user (for example, a customer of an enterprise that operates computer 301) and may take any of the forms discussed above in connection with computer 301. EUD 303 typically receives helpful and useful data from the operations of computer 301. For example, in a hypothetical case where computer 301 is designed to provide a recommendation to an end user, this recommendation would typically be communicated from network module 315 of computer 301 through WAN 302 to EUD 303. In this way, EUD 303 can display, or otherwise present, the recommendation to an end user. In some embodiments, EUD 303 may be a client device, such as thin client, heavy client, mainframe computer, desktop computer and so on.

REMOTE SERVER 304 is any computer system that serves at least some data and/or functionality to computer 301. Remote server 304 may be controlled and used by the same entity that operates computer 301. Remote server 304 represents the machine(s) that collect and store helpful and useful data for use by other computers, such as computer 301. For example, in a hypothetical case where computer 301 is designed and programmed to provide a recommendation based on historical data, then this historical data may be provided to computer 301 from remote database 330 of remote server 304.

PUBLIC CLOUD 305 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 305 is performed by the computer hardware and/or software of cloud orchestration module 341. The computing resources provided by public cloud 305 are typically implemented by virtual computing environments that run on various computers making up the computers of host physical machine set 342, which is the universe of physical computers in and/or available to public cloud 305. The virtual computing environments (VCEs) typically take the form of virtual machines from virtual machine set 343 and/or containers from container set 344. It is understood that these VCEs may be stored as images and may be transferred among and between the various physical machine hosts, either as images or after instantiation of the VCE. Cloud orchestration module 341 manages the transfer and storage of images, deploys new instantiations of VCEs and manages active instantiations of VCE deployments. Gateway 340 is the collection of computer software, hardware, and firmware that allows public cloud 305 to communicate through WAN 302.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 306 is similar to public cloud 305, except that the computing resources are only available for use by a single enterprise. While private cloud 306 is depicted as being in communication with WAN 302, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 305 and private cloud 306 are both part of a larger hybrid cloud.

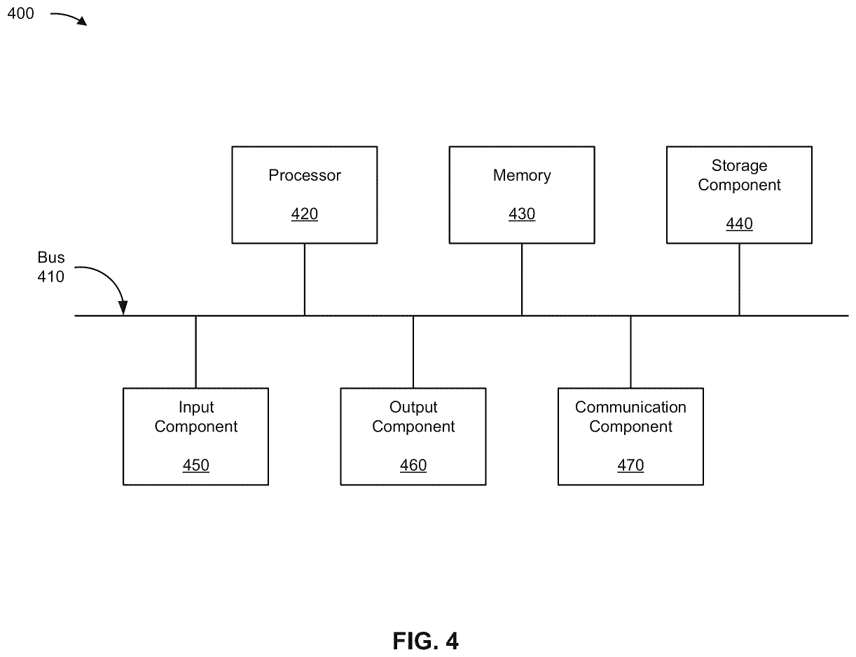

FIG. 4 is a diagram of example components of a device 400, which may implement one or more components of the computing system 100. As shown in FIG. 4, device 400 may include a bus 410, a processor 420, a memory 430, a storage component 440, an input component 450, an output component 460, and a communication component 470.

Bus 410 includes a component that enables wired and/or wireless communication among the components of device 400. Processor 420 includes a central processing unit, a graphics processing unit, a microprocessor, a controller, a microcontroller, a digital signal processor, a field-programmable gate array, an application-specific integrated circuit, and/or another type of processing component. Processor 420 is implemented in hardware, firmware, or a combination of hardware and software. In some implementations, processor 420 includes one or more processors capable of being programmed to perform a function. Memory 430 includes a random access memory, a read only memory, and/or another type of memory (e.g., a flash memory, a magnetic memory, and/or an optical memory).

Storage component 440 stores information and/or software related to the operation of device 400. For example, storage component 440 may include a hard disk drive, a magnetic disk drive, an optical disk drive, a solid state disk drive, a compact disc, a digital versatile disc, and/or another type of non-transitory computer-readable medium. Input component 450 enables device 400 to receive input, such as user input and/or sensed inputs. For example, input component 450 may include a touch screen, a keyboard, a keypad, a mouse, a button, a microphone, a switch, a sensor, a global positioning system component, an accelerometer, a gyroscope, and/or an actuator. Output component 460 enables device 400 to provide output, such as via a display, a speaker, and/or one or more light-emitting diodes. Communication component 470 enables device 400 to communicate with other devices, such as via a wired connection and/or a wireless connection. For example, communication component 470 may include a receiver, a transmitter, a transceiver, a modem, a network interface card, and/or an antenna.

Device 400 may perform one or more processes described herein. For example, a non-transitory computer-readable medium (e.g., memory 430 and/or storage component 440) may store a set of instructions (e.g., one or more instructions, code, software code, and/or program code) for execution by processor 420. Processor 420 may execute the set of instructions to perform one or more processes described herein. In some implementations, execution of the set of instructions, by one or more processors 420, causes the one or more processors 420 and/or the device 400 to perform one or more processes described herein. In some implementations, hardwired circuitry may be used instead of or in combination with the instructions to perform one or more processes described herein. Thus, implementations described herein are not limited to any specific combination of hardware circuitry and software.

The number and arrangement of components shown in FIG. 4 are provided as an example. Device 400 may include additional components, fewer components, different components, or differently arranged components than those shown in FIG. 4. Additionally, or alternatively, a set of components (e.g., one or more components) of device 400 may perform one or more functions described as being performed by another set of components of device 400.

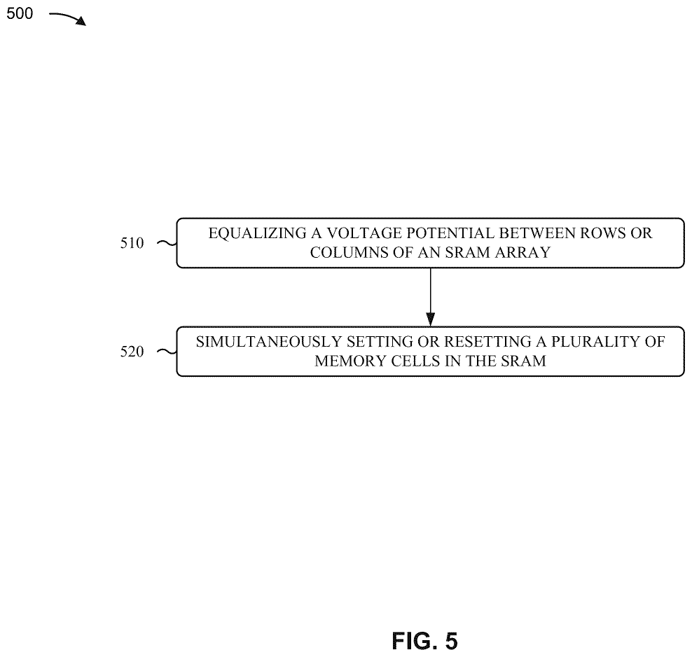

To further describe some implementations in greater detail, reference is next made to examples of techniques which may be performed by or using systems as described herein. FIG. 5 is a flowchart of an example of a technique 500 associated with managing memory in an SRAM array. The technique 500 can be executed using computing devices, such as the systems, hardware, and software described with respect to FIGS. 1-4. The technique 500 can be performed, for example, by executing a machine-readable program or other computer-executable instructions, such as routines, instructions, programs, or other code. The steps, or operations, of the technique 500, or another technique, method, process, or algorithm described in connection with the implementations disclosed herein can be implemented directly in hardware, firmware, software executed by hardware, circuitry, or a combination thereof.

For simplicity of explanation, the technique 500 is depicted and described herein as a series of steps or operations. However, the steps or operations of the technique 500 can occur in various orders and/or concurrently. Additionally, other steps or operations not presented and described herein may be used. Furthermore, not all illustrated steps or operations may be required to implement a technique in accordance with the disclosed subject matter.

At 510, the technique 500 may include equalizing a voltage potential between rows or columns of an SRAM array. The SRAM array may be part of a SRAM device such as, for example, the SRAM device 104 shown in FIG. 1 or the SRAM device 200 shown in FIG. 2. In some implementations, this equalization may be performed using an equalize component (e.g., the equalize component 268 shown in FIG. 2) of a quick-set component (e.g., the quick-set component 204 shown in FIG. 2 or the quick-set component 108 shown in FIG. 1). The equalize component may be configured to mitigate cell biasing during normal operation of the SRAM array. In some implementations, the equalize component may include a FET disposed between a first inverter and a second inverter of the quick-set component.

At 520, the technique 500 may include simultaneously setting or resetting a plurality of memory cells in the SRAM array using the quick-set component. In some implementations, this simultaneous setting or resetting may be performed on either rows or columns of the SRAM array, depending on how the quick-set component is coupled to the SRAM array. The quick-set component may be configured to implement various quick-set patterns on the rows or columns of the SRAM array, such as blanket ‘1’ patterns, blanket ‘0’ patterns, even striping patterns, odd striping patterns, or block patterns.

In some implementations, the technique 500 may include additional steps not explicitly shown in FIG. 5. For example, the technique 500 may include detecting a potential security threat, such as a side channel attack. In response to detecting the potential security threat, the technique 500 may cause the quick-set component to perform the simultaneous setting or resetting of the plurality of memory cells. This capability may be particularly useful for mitigating cache-targeted exploits during the functional mode of operation.

The quick-set component used in the technique 500 may include a first inverter associated with a first logical state and a second inverter associated with a second logical state complement to the first logical state. In some implementations, each of these inverters may include a PFET, an NFET, and a single gate control operably coupled to both the PFET and the NFET. This configuration may allow for simplified circuit design and improved switching speed.

During normal operation, the equalize component of the quick-set component may be configured to mitigate biasing by providing a stable ground voltage to the SRAM array. This may help prevent voltage fluctuations and leakage currents that could potentially disturb the stored data in the memory cells. The equalize component may thus contribute to the overall stability and reliability of the SRAM device.

In some implementations, the technique 500 may be performed as part of a larger system that includes an attack detection component configured to detect side channel attacks. When such an attack is detected, the attack detection component may trigger the quick-set component to purge the SRAM array, effectively clearing or randomizing the contents of specific memory regions or even the entire SRAM array. This action may disrupt an attacker's ability to gather meaningful information through side-channel analysis.

The technique 500 may be useful in computing systems that require high-speed data storage and retrieval capabilities while maintaining data integrity and security. By enabling rapid and simultaneous setting or resetting of multiple memory cells, the technique 500 provides a mechanism for protecting sensitive data stored in the SRAM array. This capability may be especially valuable in scenarios where immediate data purging is necessary to prevent unauthorized access or data leakage.

In some implementations, the technique 500 may be used in conjunction with other security measures to enhance the overall resilience of the system against various types of attacks. For example, the quick-set functionality may be combined with dynamic memory obfuscation techniques, periodically altering the memory layout to make it more challenging for attackers to predict and exploit branch outcomes. This approach may help reduce the consistency and predictability of branch-related data in the SRAM array, further enhancing security.

The technique 500 may also be applied in scenarios where rapid memory initialization is required, such as during system startup or when transitioning between different operational modes. By allowing for quick and efficient setting of memory states across large portions of the SRAM array, the technique 500 may contribute to faster system boot times and more responsive state transitions.

According to an aspect of the disclosure, there is provided a static random access memory (SRAM) device. The SRAM device includes an SRAM array having a plurality of memory cells arranged in rows and columns. The SRAM device also includes a quick-set component coupled to the SRAM array. The quick-set component includes an equalize component and is configured to simultaneously set or reset a plurality of the memory cells in the SRAM array. The equalize component is configured to mitigate cell biasing during a normal operation. This SRAM device improves the efficiency of memory management by enabling rapid and simultaneous modification of multiple memory cell states. Additionally, the device enhances stability and reliability of SRAM operation through the mitigation of cell biasing.

In embodiments, the quick-set component can include a first inverter associated with a first logical state and a second inverter associated with a second logical state complement to the first logical state. This configuration has the technical effect of enabling efficient implementation of complementary logic states within the quick-set component. Additionally, this arrangement simplifies the circuit design and reduces the number of control signals required.

In embodiments, the first inverter can comprise a P-channel field effect transistor (PFET), an N-channel field effect transistor (NFET), and a single gate control operably coupled to both the PFET and the NFET of the first inverter. This structure has the technical effect of improving switching speed by ensuring that the PFET and NFET transition states simultaneously. Additionally, this configuration reduces circuit complexity, which can lead to easier implementation in dense memory arrays.

In embodiments, the second inverter can comprise a P-channel field effect transistor (PFET), an N-channel field effect transistor (NFET), and a single gate control operably coupled to both the PFET and the NFET of the second inverter. This arrangement has the technical effect of providing symmetrical operation with the first inverter, ensuring balanced performance across the quick-set component.

In embodiments, the equalize component can comprise a field effect transistor (FET) disposed between the first inverter and the second inverter. This configuration has the technical effect of providing a controllable connection between the true and complement sides of the quick-set component, enabling effective mitigation of voltage differentials and cell biasing.

In embodiments, during a normal operation, the equalize component can be configured to mitigate biasing by providing a stable ground voltage to the SRAM array. This feature has the technical effect of preventing voltage fluctuations and leakage currents that could potentially disturb the stored data in the memory cells. Additionally, this configuration contributes to the overall stability and reliability of the SRAM device.

In embodiments, the quick-set component can be coupled to the rows of the SRAM array. This arrangement has the technical effect of enabling efficient row-wise operations, which can be particularly beneficial for certain memory access patterns and data manipulation tasks.

In embodiments, the quick-set component can be configured to simultaneously set or reset a plurality of wordlines within the SRAM array. This capability has the technical effect of allowing rapid initialization or clearing of entire rows of memory cells, which can significantly improve the speed of memory management operations.

In embodiments, the quick-set component can be configured to implement at least one quick-set pattern on the rows of the SRAM array. This feature has the technical effect of enabling flexible and efficient memory initialization patterns, which can be useful for testing, diagnostics, and certain computational algorithms.

In embodiments, the quick-set component can be configured to perform a reset operation based on a detection of a side channel attack. This capability has the technical effect of providing a rapid response mechanism to potential security threats, enhancing the overall security of the SRAM device.

According to another aspect of the disclosure, there is provided a computing system. The computing system includes an attack detection component configured to detect a side channel attack. The system also includes a static random access memory (SRAM) device. The SRAM device comprises an SRAM array having a plurality of memory cells arranged in rows and columns, and a quick-set component coupled to the SRAM array. The quick-set component is configured to, based on an indication of a detection of the side channel attack, simultaneously set or reset a plurality of the memory cells in the SRAM array. This system improves the security of SRAM-based computing systems by providing a rapid response mechanism to potential side channel attacks. Additionally, the system enhances the overall reliability and integrity of data stored in the SRAM array.

In embodiments, the quick-set component can include a first inverter associated with a first logical state, a second inverter associated with a second logical state complement to the first logical state, and an equalize component configured to mitigate cell biasing during a normal operation. This configuration has the technical effect of enabling efficient implementation of complementary logic states while maintaining stable operation through cell bias mitigation.

In embodiments, the equalize component can comprise a field effect transistor (FET) disposed between the first inverter and the second inverter. This arrangement has the technical effect of providing a controllable connection between the true and complement sides of the quick-set component, enabling effective mitigation of voltage differentials and cell biasing.

In embodiments, the quick-set component can be coupled to the rows or the columns of the SRAM array. This flexibility has the technical effect of allowing the system to be optimized for different memory access patterns and data manipulation tasks, depending on the specific requirements of the application.

In embodiments, the attack detection component can be configured to trigger the quick-set component to purge the SRAM array upon detection of the side channel attack. This feature has the technical effect of providing an immediate and comprehensive response to potential security threats, minimizing the window of vulnerability for sensitive data stored in the SRAM array.

In embodiments, the computing system can be configured to operate in a functional mode, and the quick-set component can be activated during the functional mode to mitigate cache-targeted exploits. This capability has the technical effect of providing ongoing protection against security threats without interrupting normal system operation, enhancing both security and system availability.

According to yet another aspect of the disclosure, there is provided a computer-implemented method. The method includes equalizing, using an equalize component of a quick-set component, a voltage potential between rows or columns of a static random access memory (SRAM) array. The method also includes simultaneously setting or resetting a plurality of the memory cells in the SRAM array using the quick-set component. This method improves the efficiency of SRAM management by enabling rapid and simultaneous modification of multiple memory cell states. Additionally, the method enhances the stability and reliability of SRAM operation through the equalization of voltage potentials.

In embodiments, the method can include detecting a potential security threat and, responsive to detecting the potential security threat, causing the quick-set component to perform the simultaneously setting or resetting of the plurality of the memory cells. This feature has the technical effect of providing a rapid response mechanism to potential security threats, enhancing the overall security of the SRAM device.

In embodiments, the simultaneously setting or resetting can comprise implementing at least one quick-set pattern on the rows of the SRAM array. This capability has the technical effect of enabling flexible and efficient memory initialization patterns, which can be useful for testing, diagnostics, and certain computational algorithms.

In embodiments, the at least one quick-set pattern can comprise at least one of a blanket ‘1’ pattern, a blanket ‘0’ pattern, an even striping pattern, an odd striping pattern, or a block pattern. These patterns have the technical effect of providing a range of initialization options, allowing for efficient implementation of various memory states required for different applications or security protocols.

The SRAM device includes an SRAM array with memory cells arranged in rows and columns, and a quick-set component coupled to the array. The quick-set component has an equalize component and can simultaneously set or reset multiple memory cells in the array. The equalize component mitigates cell biasing during normal operation. The quick-set component includes a first inverter for a first logical state and a second inverter for a second logical state complement to the first logical state. The first inverter has a PFET, an NFET, and a single gate control coupled to both transistors. This configuration enables efficient and simultaneous modification of multiple memory cells while maintaining stability through bias mitigation. The single gate control for each inverter simplifies the circuit design and improves switching speed by ensuring synchronized transistor state transitions.

The SRAM device includes an SRAM array with memory cells arranged in rows and columns, and a quick-set component coupled to the array. The quick-set component has an equalize component and can simultaneously set or reset multiple memory cells in the array. The equalize component mitigates cell biasing during normal operation. The quick-set component includes a first inverter for a first logical state and a second inverter for a second logical state complement to the first logical state. The second inverter has a PFET, an NFET, and a single gate control coupled to both transistors. This arrangement provides efficient memory cell modification capabilities while maintaining operational stability. The symmetrical design of both inverters ensures balanced performance across the quick-set component, contributing to the overall reliability of the SRAM device.

The SRAM device includes an SRAM array with memory cells arranged in rows and columns, and a quick-set component coupled to the array. The quick-set component has an equalize component and can simultaneously set or reset multiple memory cells in the array. The equalize component mitigates cell biasing during normal operation. The quick-set component is coupled to the rows of the SRAM array. This configuration enables efficient row-wise operations, which can significantly improve the speed and effectiveness of memory management tasks. The ability to operate on entire rows simultaneously allows for rapid initialization or clearing of large portions of memory, which is particularly beneficial for certain memory access patterns and data manipulation tasks.

The SRAM device includes an SRAM array with memory cells arranged in rows and columns, and a quick-set component coupled to the array. The quick-set component has an equalize component and can simultaneously set or reset multiple memory cells in the array. The equalize component mitigates cell biasing during normal operation. The quick-set component is configured to perform a reset operation based on a detection of a side channel attack. This combination provides a rapid response mechanism to potential security threats, enhancing the overall security of the SRAM device. The ability to quickly reset memory contents upon detection of an attack helps prevent unauthorized access to sensitive data and mitigates the risk of information leakage through side-channel vulnerabilities.

The computing system includes an attack detection component configured to detect a side channel attack and an SRAM device. The SRAM device has an array of memory cells in rows and columns, and a quick-set component coupled to the array. The quick-set component can simultaneously set or reset multiple memory cells based on an indication of a detected side channel attack. The quick-set component includes a first inverter for a first logical state, a second inverter associated with a second logical state complement to the first logical state, and an equalize component to mitigate cell biasing during normal operation. This configuration provides a comprehensive security solution by combining attack detection with rapid memory content modification. The equalize component ensures stable operation during normal use, while the quick-set capability allows for immediate response to detected threats, enhancing the overall integrity and security of the stored data.

The computing system includes an attack detection component configured to detect a side channel attack and an SRAM device. The SRAM device has an array of memory cells in rows and columns, and a quick-set component coupled to the array. The quick-set component can simultaneously set or reset multiple memory cells based on an indication of a detected side channel attack. The quick-set component is coupled to the rows or the columns of the SRAM array. This arrangement provides flexibility in implementing security measures, allowing the system to be optimized for different memory access patterns and data manipulation tasks. The ability to operate on either rows or columns enables efficient and targeted memory content modification in response to detected threats, improving the system's overall security posture.

The computing system includes an attack detection component configured to detect a side channel attack and an SRAM device. The SRAM device has an array of memory cells in rows and columns, and a quick-set component coupled to the array. The quick-set component can simultaneously set or reset multiple memory cells based on an indication of a detected side channel attack. The attack detection component is configured to trigger the quick-set component to purge the SRAM array upon detection of the side channel attack. This combination provides an immediate and comprehensive response to potential security threats, minimizing the window of vulnerability for sensitive data stored in the SRAM array. The automatic triggering of the purge operation ensures a rapid reaction to detected attacks, significantly enhancing the system's ability to protect against data breaches and unauthorized access.

The computer-implemented method involves equalizing a voltage potential between rows or columns of an SRAM array using an equalize component of a quick-set component, and simultaneously setting or resetting multiple memory cells in the array using the quick-set component. The method also includes detecting a potential security threat and, in response, causing the quick-set component to perform the simultaneous setting or resetting of the memory cells. This approach combines proactive security measures with efficient memory management. The ability to quickly respond to detected threats by modifying memory contents enhances the system's resilience against attacks, while the equalization process ensures stable and reliable operation during normal use.

The computer-implemented method involves equalizing a voltage potential between rows or columns of an SRAM array using an equalize component of a quick-set component, and simultaneously setting or resetting multiple memory cells in the array using the quick-set component. The simultaneous setting or resetting involves implementing at least one quick-set pattern on the rows of the SRAM array. This method enables flexible and efficient memory initialization patterns, which are useful for testing, diagnostics, and certain computational algorithms. The ability to rapidly apply predefined patterns across rows of memory cells can significantly improve the speed and effectiveness of memory management tasks, particularly in scenarios requiring specific data configurations or rapid memory clearing.

The computer-implemented method involves equalizing a voltage potential between rows or columns of an SRAM array using an equalize component of a quick-set component, and simultaneously setting or resetting multiple memory cells in the array using the quick-set component. The simultaneous setting or resetting involves implementing at least one quick-set pattern on the rows of the SRAM array. The quick-set pattern includes at least one of a blanket ‘1’ pattern, a blanket ‘0’ pattern, an even striping pattern, an odd striping pattern, or a block pattern. This combination provides a range of initialization options, allowing for efficient implementation of various memory states required for different applications or security protocols. The diverse pattern options enable tailored memory configurations, which can be particularly useful for specific testing scenarios, data obfuscation techniques, or optimizing memory layout for certain algorithms.

In one implementation, the quick-set component of the SRAM device is utilized to mitigate cache-targeted exploits during the functional mode of operation. When the attack detection component identifies a potential side-channel attack, such as a Spectre or Meltdown-based exploit, it triggers the quick-set component to rapidly purge the contents of the SRAM array. For example, if a malicious program attempts to exploit speculative execution to access sensitive data stored in the cache, the quick-set component can immediately implement a blanket ‘O’ pattern across all rows of the SRAM array. This action effectively clears all data, including any potentially compromised information, within a fraction of the time required by conventional sequential writing methods. By rapidly resetting the memory contents, the invention significantly reduces the window of opportunity for attackers to extract sensitive data through cache timing or other side-channel techniques.

In another scenario, the invention's capability to implement various quick-set patterns is employed for efficient memory initialization in high-performance computing applications. For instance, when initializing a large SRAM array for a complex numerical simulation, the quick-set component can apply a striping even pattern to the rows of the array. This pattern alternates between setting rows to all ‘1’s and all ‘0’s, creating a predefined data structure that can be utilized by the simulation algorithm. The ability to rapidly establish this pattern across the entire array significantly reduces the initialization time compared to traditional methods of sequentially writing to each memory cell. As a result, the overall execution time of the simulation is decreased, allowing for more iterations or larger datasets to be processed within a given timeframe.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

As used herein, the term “component” is intended to be broadly construed as hardware, firmware, or a combination of hardware and software. It will be apparent that systems and/or methods described herein may be implemented in different forms of hardware, firmware, and/or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be used to implement the systems and/or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Although particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A static random access memory (SRAM) device, comprising:
an SRAM array having memory cells arranged in rows and columns; and
a quick-set component coupled to the SRAM array, the quick-set component including an equalize component and being configured to simultaneously set or reset a plurality of the memory cells in the SRAM array, wherein the equalize component is configured to mitigate cell biasing during a normal operation.

2. The SRAM device of claim 1, wherein the quick-set component further includes:
a first inverter associated with a first logical state; and
a second inverter associated with a second logical state complement to the first logical state.

3. The SRAM device of claim 2, wherein the first inverter comprises a first P-channel field effect transistor (PFET), a first N-channel field effect transistor (NFET), and a first single gate control operably coupled to the first PFET and the first NFET; and wherein the second inverter comprises a second PFET, a second NFET, and a second single gate control operably coupled to the second PFET and the second NFET.

4. The SRAM device of claim 2, wherein the equalize component comprises a field effect transistor (FET), the FET being disposed between the first inverter and the second inverter.

5. The SRAM device of claim 1, wherein, during a normal operation, the equalize component is configured to mitigate biasing by providing a stable ground voltage to the SRAM array.

6. The SRAM device of claim 1, wherein the quick-set component is coupled to the rows of the SRAM array.

7. The SRAM device of claim 6, wherein the quick-set component is configured to simultaneously set or reset a plurality of wordlines within the SRAM array.

8. The SRAM device of claim 6, wherein the quick-set component is configured to implement at least one quick-set pattern on the rows of the SRAM array.

9. The SRAM device of claim 8, wherein the at least one quick-set pattern comprises at least one of a blanket ‘1’ pattern, a blanket ‘0’ pattern, an even striping pattern, an odd striping pattern, and a block pattern.

10. The SRAM device of claim 1, wherein the quick-set component is configured to perform a reset operation based on a detection of a side channel attack.

11. A computing system, comprising:
an attack detection component configured to detect a side channel attack; and
a static random access memory (SRAM) device, comprising:
an SRAM array having memory cells arranged in rows and columns; and
a quick-set component coupled to the SRAM array and configured to, based on an indication of a detection of the side channel attack, simultaneously set or reset a plurality of the memory cells in the SRAM array.

12. The computing system of claim 11, wherein the quick-set component includes:
a first inverter associated with a first logical state;
a second inverter associated with a second logical state complement to the first logical state; and
an equalize component configured to mitigate cell biasing during a normal operation.

13. The computing system of claim 12, wherein the equalize component comprises a field effect transistor (FET) disposed between the first inverter and the second inverter.

14. The computing system of claim 11, wherein the quick-set component is coupled to the rows or the columns of the SRAM array.

15. The computing system of claim 11, wherein the attack detection component is configured to trigger the quick-set component to purge the SRAM array upon detection of the side channel attack.

16. The computing system of claim 11, wherein the computing system is configured to operate in a functional mode, and the quick-set component is activated during the functional mode to mitigate cache-targeted exploits.

17. A computer-implemented method, comprising:
equalizing, using an equalize component of a quick-set component, a voltage potential between rows or columns of a static random access memory (SRAM) array; and
simultaneously setting or resetting a plurality of memory cells in the SRAM array using the quick-set component.

18. The computer-implemented method of claim 17, further comprising:
detecting a potential security threat; and
responsive to detecting the potential security threat, causing the quick-set component to perform the simultaneously setting or resetting of the plurality of the memory cells.

19. The computer-implemented method of claim 17, wherein the simultaneously setting or resetting comprises implementing at least one quick-set pattern on the rows of the SRAM array.

20. The computer-implemented method of claim 19, wherein the at least one quick-set pattern comprises at least one of a blanket ‘1’ pattern, a blanket ‘0’ pattern, an even striping pattern, an odd striping pattern, or a block pattern.
